(19) United States
(12) Patent Application Publication
(10) Pub. No.: US 2026/0368700 A1
(43) Pub. Date: Nov. 19, 2026

(54) WORK ASSISTANCE METHOD AND WORK ASSISTANCE SYSTEM

(71) Applicant: SCREEN Holdings Co., Ltd., Kyoto (JP)

(72) Inventors: Shinji SHIMIZU, Kyoto-shi, Kyoto (JP); Akihiro MINOGUCHI, Kyoto-shi, Kyoto (JP)

(21) Appl. No.: 19/142,919

(22) PCT Filed: Dec. 6, 2023
(86) PCT No.: PCT/JP2023/043627

§ 371 Date: Jun. 24, 2025

(30) Foreign Application Priority Data
Dec. 28, 2022 (JP) 2022-211070

(51) Int. Cl. G06Q 10/20

(52) U.S. Cl. CPC G06Q 10/20

(57) ABSTRACT

A large number of substrate processing apparatuses are disposed side by side in a clean room. A plurality of processing units are provided to one substrate processing apparatus. A maintenance worker locates a virtual object in an image of a region included in the substrate processing apparatus taken by a smart glass. A position where the virtual object is disposed is set as a reference position. A relative positional relationship of a portion included in the substrate processing apparatus with respect to the reference position is calculated and recorded. When the maintenance worker inputs a search instruction of designating the substrate processing apparatus to be worked on from the smart glass, the smart glass specifies a position of the substrate processing apparatus to be searched based on the relative positional relationship with respect to the reference position, and displays the positional information thereof.

### TECHNICAL FIELD

The present invention relates to a work assistance method and a work assistance system assisting a work in performing a maintenance work on a substrate processing apparatus performing predetermined processing such as cleaning processing on a substrate. Examples of a substrate to be processed by the substrate processing apparatus include a semiconductor substrate, a liquid crystal display apparatus substrate, a flat panel display (FPD) substate, an optical disk substrate, a magnetic disk substrate, or a solar cell substrate.

### BACKGROUND ART

A substrate processing apparatus performing various types of processing on a substate such as a semiconductor substrate is conventionally used in a process of manufacturing a semiconductor device. A substrate cleaning apparatus, a heat treatment apparatus, and an inspection apparatus, for example, are used as the substrate processing apparatus. Typically, a number of same type of substrate processing apparatuses are systematically disposed in a large clean room in many cases. For example, Patent Document 1 describes that a number of substrate processing apparatuses are disposed in a clean room to be arranged at a relatively high density in a manufacturing plant of a semiconductor device.

The substrate processing apparatus generally includes a plurality of processing units performing precise processing and a transport robot, and a maintenance work needs to be performed on the substrate processing apparatus regularly or irregularly. In the clean room where a number of substrate processing apparatuses are disposed, a worker finds a substrate processing apparatus on which a maintenance work is to be performed, and performs a maintenance work necessary for the substrate processing apparatus.

### PRIOR ART DOCUMENTS

### Patent Document(s)

Patent Document 1: Japanese Patent Application Laid-Open No. 2020-4866

### SUMMARY

### Problem to be Solved by the Invention

A number of same type of substrate processing apparatuses are systematically disposed in the clean room in many cases. They are distinguished by identification numbers individually assigned to the substrate processing apparatuses, but have the same appearance. Thus, the worker makes a mistake in selecting the substrate processing apparatus on which the maintenance work is to be performed. Although taken are measures that a worker reads the identification number aloud to confirm the substrate processing apparatus, for example, the worker still makes a mistake in selecting the substrate processing apparatus on which the maintenance work is to be performed in some cases.

A plurality of processing units having the same shape are provided in one substrate processing apparatus. Thus, there is concern that it takes time for the worker to confirm the processing unit to be worked on or the worker makes a mistake in selecting the processing unit at worst.

Furthermore, an accessory unit is provided to the substrate processing apparatus separately from a body. For example, a chemical solution cabinet is provided to be separated from a body in a substrate cleaning apparatus using a chemical solution. When such an accessory unit is disposed in a floor different from that of the body of the substrate processing apparatus, there also arises a problem that it is difficult for the worker to identify the accessory unit corresponding to the substrate processing apparatus to be worked on.

The present invention is therefore has been made to solve the above problems, and it is an object to provide a work assistance method and a work assistance system capable of easily recognizing a substrate processing apparatus to be worked on.

### Means to Solve the Problem

In order to solve the above problems, a first aspect of the present invention is a work assistance method on a substrate processing apparatus performing predetermined processing on a substrate, including: a reference position setting step of setting a reference position with respect to the substrate processing apparatus in a taken image obtained by taking an image of a substrate processing apparatus by a mobile terminal including an imaging part and a communication part; a positional information recording step of calculating and recording a relative positional relationship between at least one portion included in the substrate processing apparatus and the reference position; and a displaying step of specifying a position of a portion included in a substrate processing apparatus to be searched from recorded contents in the positional information recording step when a search instruction of designating a portion included in a substrate processing apparatus to be worked on is inputted from the mobile terminal and displaying positional information of the position.
A second aspect is the work assistance method according to the first aspect, wherein in the displaying step, a search instruction of designating the substrate processing apparatus to be worked on is inputted, a position of the substrate processing apparatus to be searched is specified, and a guide route to the substrate processing apparatus is displayed.
A third aspect is a work assistance method according to the first or second aspect, further including an individual information recording step of associating individual information of a portion recorded in the positional information recording step with the portion and recording the individual information, wherein the mobile terminal further displays the individual information associated with a portion included in the substrate processing apparatus to be searched.
A fourth aspect is the work assistance method according to the third aspect, wherein the individual information includes at least one piece of information selected from a group of alarm information, a work history, diagram information, a work procedure document, and a name label.
A fifth aspect is the work assistance method according to any one of the first to fourth aspects, wherein in the reference position setting step, a virtual object is disposed on a spatial mesh obtained by scanning the taken image to set the reference position.
A sixth aspect is the work assistance method according to any one of the first to fifth aspects, wherein the substrate processing apparatus includes a plurality of processing units, in the positional information recording step, a relative positional relationship between a portion included in each of the plurality of processing units and the reference position is individually calculated and recorded, and in the displaying step, positional information of a portion included in each of the processing units is displayed when search instruction of designating any portion included in the plurality of processing units is inputted from the mobile terminal.
A seventh aspect is the work assistance method according to the sixth aspect, wherein in the positional information recording step, a CAD diagram of the substrate processing apparatus is overlapped with the substrate processing apparatus in the taken image, and a relative positional relationship between a portion included in each of the plurality of processing units and the reference position is individually calculated.
An eighth aspect is the work assistance method according to the sixth aspect, wherein an accessory unit as an accessory of the substrate processing apparatus is provided separately from the substrate processing apparatus, in the reference position setting step, an accessory reference position associated with the reference position is further set for the accessory unit, in the positional information recording step, a relative positional relationship between a portion included in the accessory unit and the accessory reference position is further recorded, and in the displaying step, positional information of the accessory unit is displayed when a search instruction of designating the accessory unit is inputted from the mobile terminal.
A ninth aspect is the work assistance method according to the sixth aspect, wherein in the displaying step, predetermined image processing is performed on a taken image to identify an element included in each of the processing units and display the positional information when an image of any of the plurality of processing units is taken and a detection instruction is inputted in the mobile terminal.
A tenth aspect is the work assistance method according to any one of the first to ninth aspects, wherein the mobile terminal is a smart glass.
An eleventh aspect is a work assistance system for a substrate processing apparatus performing predetermined processing on a substrate, including: a plurality of substrate processing apparatuses; a mobile terminal including a imaging part and a communication part; a reference position setting part setting a reference position with respect to at least one of the plurality of substrate processing apparatuses in a taken image obtained by taking an image of the at least one of the plurality of substrate processing apparatuses by the mobile terminal; a positional information recording part calculating and recording a relative positional relationship between at least one portion included in the substrate processing apparatuses and the reference position; and a position specifying part specifying a position of a portion included in a substrate processing apparatus to be searched from recorded contents by the positional information recording part when a search instruction of designating a portion included in the substrate processing apparatus to be worked on is inputted from the mobile terminal and displaying positional information of the position by the mobile terminal.
A twelfth aspect is a work assistance system according to the eleventh aspect, further including an individual information recording part associating individual information of a portion recorded by the positional information recording part with the portion and recording the individual information, and the position specifying part further displays the individual information associated with the substrate processing apparatus to be searched.
A thirteenth aspect is the work assistance system according to the twelfth aspect, wherein the individual information includes at least one piece of information selected from a group of alarm information, a work history, diagram information, a work procedure document, and a name label.
A fourteenth aspect is the work assistance system according to any one of the eleventh to thirteenth aspects, wherein the mobile terminal is a smart glass.

### Effects of the Invention

According to the work assistance method according to the first to tenth aspects, the reference position with respect to the substrate processing apparatus is set in the taken image; the relative positional relationship between at least one portion included in the substrate processing apparatus and the reference position is calculated and recorded; and the position of the portion included in the substrate processing apparatus to be searched is specified when the search instruction of designating the portion included in the substrate processing apparatus to be worked on is inputted from the mobile terminal and the positional information of the position is displayed. Thus, even when the plurality of substrate processing apparatuses having similar appearances are arranged, the worker can easily recognize the substrate processing apparatus to be worked on.

Particularly, according to the work assistance method in the second aspect, the guide route to the substrate processing apparatus is displayed. Thus, the worker can reach the target substrate processing apparatus without mistake along the guide route.

According to the work assistance system according to the eleventh to fourteenth aspects, the reference position with respect to the substrate processing apparatus is set in the taken image; the relative positional relationship between at least one portion included in the substrate processing apparatus and the reference position is calculated and recorded; and the position of the portion included in the substrate processing apparatus to be searched is specified when the search instruction of designating the portion included in the substrate processing apparatus to be worked on is inputted from the mobile terminal and the positional information of the position is displayed. Thus, even when the plurality of substrate processing apparatuses having similar appearances are arranged, the worker can easily recognize the substrate processing apparatus to be worked on.

### BRIEF DESCRIPTION OF DRAWINGS

FIG. 1 is a diagram schematically illustrating a schematic configuration of a work assistance system according to the present invention.

FIG. 2 is a plan view illustrating an example of a layout of a plurality of substrate processing apparatuses.

FIG. 3 is a side view illustrating an example of an arrangement of a plurality of substrate processing apparatuses.

FIG. 4 is a diagram illustrating a configuration of one substrate processing apparatus.

FIG. 5 is a diagram illustrating a schematic configuration of a processing unit.

FIG. 6 is a perspective view illustrating an appearance of a smart glass.

FIG. 7 is a block diagram illustrating a functional configuration of a smart glass, a server, and a work assistance terminal.

FIG. 8 is a flow chart illustrating a procedure of the work assistance method according to the present invention.

FIG. 9 is a flow chart illustrating a procedure of the work assistance method according to the present invention.

FIG. 10 is a diagram illustrating an example of an taken image converted into a form of a spatial mesh.

FIG. 11 is a diagram schematically illustrating a relative positional relationship between a reference position and each portion of the substrate processing apparatus.

FIG. 12 is a diagram illustrating an example of a database in which positional information and individual information are recorded.

FIG. 13 is a diagram illustrating an example of the positional information of the substrate processing apparatus.

FIG. 14 is a diagram illustrating an example of display of the positional information of the processing unit.

FIG. 15 is a diagram illustrating an example of display of the individual information.

### DESCRIPTION OF EMBODIMENT(S)

Embodiments according to the present invention will now be described in detail with reference to the diagrams. In the description hereinafter, unless otherwise noted, the expressions indicating relative or absolute positional relationships (e.g., “in one direction”, “along one direction”, “parallel”, “orthogonal”, “central”, “concentric”, and “coaxial”) include those exactly indicating the positional relationships and those where an angle or a distance is relatively changed within tolerance or to the extent that similar functions can be obtained. Unless otherwise noted, the expressions indicating equality (e.g., “same”, “equal”, and “uniform”) include those indicating quantitatively exact equality and those in the presence of a difference within tolerance or to the extent that similar functions can be obtained. Unless otherwise noted, the expressions indicating shapes (e.g., “circular”, “rectangular”, and “cylindrical”) include those indicating geometrically exact shapes and those indicating, for example, roughness or a chamfer to the extent that similar effect can be obtained. An expression “comprising”, “including”, or “having” a certain constituent element is not an exclusive expression for excluding the presence of the other constituent elements. An expression “at least one of A, B, and C” involves “only A”, “only B”, “only C”, “arbitrary two of A, B, and C”, and “all of A, B, and C”.

### First Embodiment

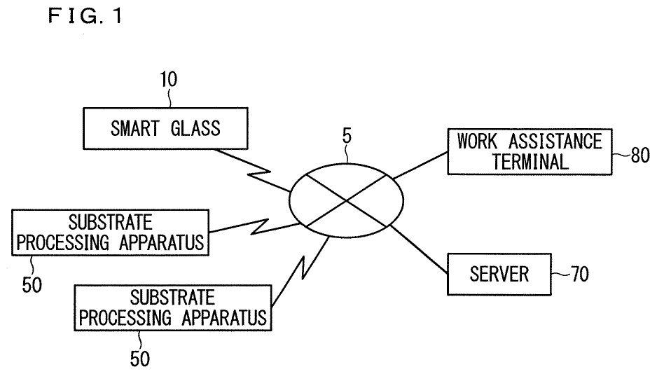

FIG. 1 is a diagram schematically illustrating a schematic configuration of a work assistance system according to the present invention. The work assistance system according to the present invention includes a plurality of substrate processing apparatuses 50, a smart glass 10, a server 70, and a work assistance terminal 80. Controllers of the smart glass 10 and the substrate processing apparatus 50 are connected to an information communication network 5 (for example, Internet) via wireless communication. The work assistance terminal 80 and the server 70 are connected to the information communication network 5 by wire. Information can be mutually transmitted and received between apparatuses connected to the information communication network 5, and information can be provided and received between the smart glass 10 and the work assistance terminal 80, for example. Whether each apparatus and the information communication network 5 are connected wirelessly or by wire is not limited to the above example. However, an appropriate configuration is applicable (for example, the work assistance terminal 80 and the information communication network 5 may be wirelessly connected.)

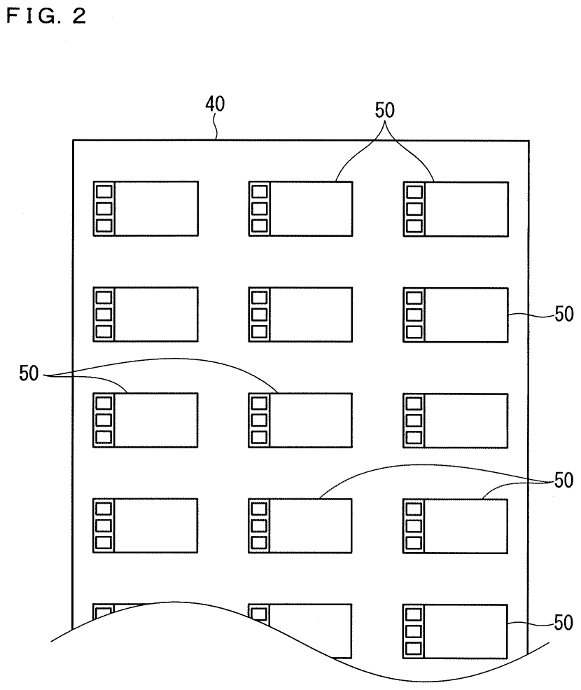

FIG. 2 is a plan view illustrating an example of a layout of the plurality of substrate processing apparatuses 50. As illustrated in FIG. 2, the plurality of substrate processing apparatuses 50 are regularly disposed side by side at regular intervals in the clean room 40. The clean room 40 is provided in a manufacturing plant of a semiconductor device, for example, and is a room in which constant air cleanliness is ensured and a temperature and humidity are managed. In the first embodiment, the same type and the same form of the plurality of substrate processing apparatuses 50 are disposed in the relatively large clean room 40. Accordingly, it is difficult for the worker to distinguish the substrate processing apparatus 50 disposed in the clean room 40 from an appearance.

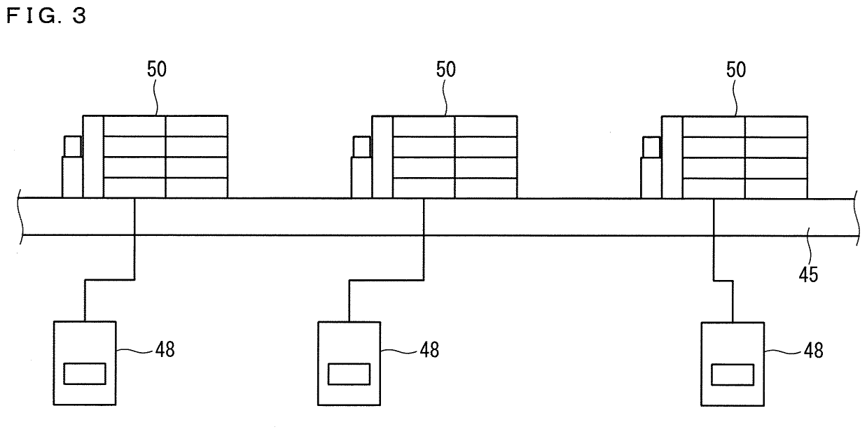

FIG. 3 is a side view illustrating an example of an arrangement of the plurality of substrate processing apparatuses 50. An accessory unit 48 is provided to the substrate processing apparatus 50 separately from a body. For example, when the substrate processing apparatus 50 is a substrate cleaning apparatus using a chemical solution, a chemical solution cabinet supplying a chemical solution to the substrate processing apparatus 50 is provided as the accessory unit. For example, when the substrate processing apparatus 50 is a heat treatment apparatus emitting light from a lamp to the substrate, a power source unit supplying electrical power to the lamp of the substrate processing apparatus 50 is provided as the accessory unit. The accessory unit 48 is provided separately from the substrate processing apparatus 50. In the present embodiment, the substrate processing apparatus 50 is disposed on a floor 45 of the clean room 40, and the accessory unit 48 is provided below the floor 45. The substrate processing apparatus 50 on the floor is connected to the corresponding accessory unit 48 below the floor by a pipe or a cable passing through the floor 45. In the present embodiment, the plurality of substrate processing apparatuses 50 and the plurality of accessory units 48 correspond to each other on a one-to-one basis.

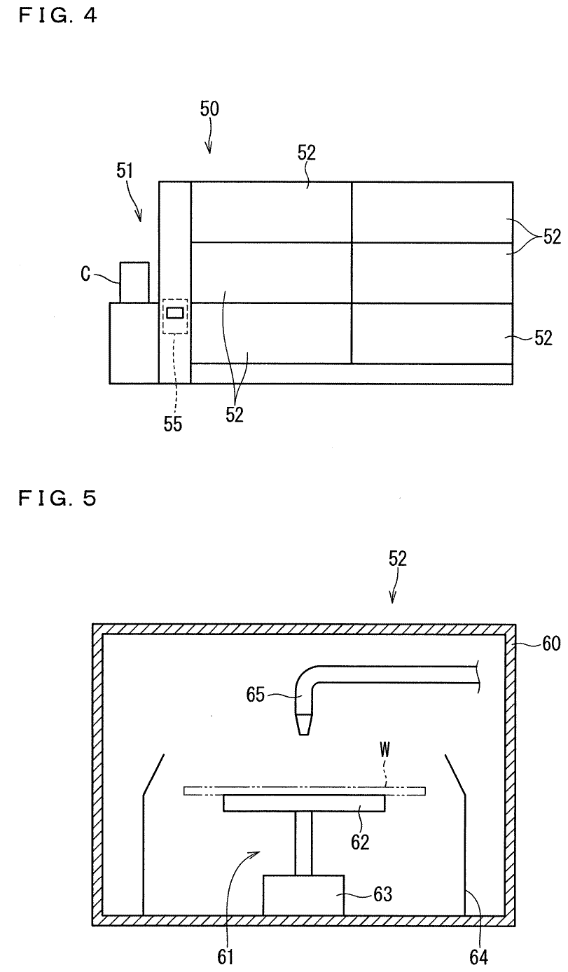

FIG. 4 is a diagram illustrating a configuration of one substrate processing apparatus 50. In the first embodiment, the substrate processing apparatus 50 is a single wafer type substrate cleaning apparatus cleaning a substrate one by one, for example. The substrate processing apparatus 50 includes an indexer 51 and a plurality of processing units 52. A carrier C housing a plurality of substrates is disposed on the indexer 51. The indexer 51 takes out an unprocessed substrate from the disposed carrier C by a transfer robot not shown in the diagrams. The indexer 51 houses the substrate which has been processed in the carrier C by the transfer robot. The carrier C is a front opening unified pod (FOUP) housing the substrate in an enclosed space, for example.

In the first embodiment, three processing units 52 are stacked to constitute one laminated body, for example. Four laminated bodies are disposed around a main transport robot not shown in the diagrams, for example. That is to say, one substrate processing apparatus 50 includes twelve processing units 52, for example.

The main transport robot disposed at a center of four laminated bodies transports an unprocessed substrate received from the transfer robot described above into any of twelve processing units 52. The main transport robot transports the substate which has been processed from the processing unit 52 and passes the substate to the transfer robot.

The substrate processing apparatus 50 includes a controller 55. The controller 55 is a general computer, and controls an operation of the transfer robot, the main transport robot, and each processing unit 52 described above in the apparatus. The controller 55 includes a touch panel as an input-output interface provided to a wall surface of the apparatus and a communication part having communication with an outer part of the apparatus.

FIG. 5 is a diagram illustrating a schematic configuration of the processing unit 52. The processing unit 52 includes a processing chamber 60, a rotation holding part 61, and a discharge nozzle 65. The processing chamber 60 is a hollow housing. The rotation holding part 61 and the discharge nozzle 65, for example, are provided inside the processing chamber 60. A transfer port not shown in the diagrams is provided to the processing chamber 60. The transfer port is opened and closed by a shutter. The main transport robot transports a substrate W into and out of the processing chamber 60 while the transfer port is opened. The transfer port is closed during processing on the substrate W. A gas supply mechanism and an exhaust mechanism not shown are provided to the processing chamber 60.

The rotation holding part 61 includes a spin chuck 62 and a spin motor 63. The spin chuck 62 is a substrate holding part holding the substrate W in a horizontal posture (posture in which a normal line of a main surface of the substrate W follows a vertical direction). The spin chuck 62 is a vacuum suction chuck, for example. The spin chuck 62 sucks and holds a center part of a lower surface of the substrate W. The spin chuck 62 may be a chuck in the other form such as a grasping-type mechanical chuck.

The spin chuck 62 has a disk-like shape with a diameter smaller than the substrate W. In a state where the lower surface of the substrate W is sucked and held by the spin chuck 62, the peripheral edge part of the substrate W protrudes to an outer side of an outer surrounding end of the spin chuck 62.

The spin chuck 62 is connected to the spin motor 63 via a motor shaft. That is to say, an upper end of the motor shaft of the spin motor 63 is connected to a center part of the lower surface of the spin chuck 62. When the spin motor 63 rotates the motor shaft while the substrate W is sucked and held by the spin chuck 62, the substrate W and the spin chuck 62 are rotated in a horizontal plane around a central axis along the vertical direction.

A cup 64 is provided to surround the spin chuck 62. The cup 64 has a cylindrical shape, and an upper part of the cup 64 is inclined to get closer to the spin chuck 62 toward an upper side. However, an inner diameter of an upper end part of the cup 64 is larger than the diameter of the substrate W. The upper end of the cup 64 is located in a higher position than a height position of the substrate W held by the spin chuck 62. Accordingly, a liquid flying in all directions from the substrate W rotated by the spin motor 63 by centrifugal force is received by the cup 64 and collected. The liquid collected by the cup 64 is discharged from a discharge solution pipe provided to a bottom part of the cup 64. The cup 64 may have a multi-stage structure that a plurality of collection ports are provided for various purposes.

The discharge nozzle 65 discharges a processing solution to the substrate W held by the spin chuck 62. The processing solution is a conceptual term including various types of chemical solutions and pure water. Examples of the chemical solution include a solution for performing etching processing or a solution for removing particles, and applied specifically is an SC-1 solution (a mixed solution of ammonium hydroxide, hydrogen peroxide water, and pure water), an SC-2 solution (a mixed solution of hydrochloric acid, hydrogen peroxide water, and pure water), or hydrofluoric acid, for example. The discharge nozzle 65 is moved between a processing position above the spin chuck 62 and a standby position outside the cup 64 by a drive mechanism not shown in the diagrams. When the discharge nozzle 65 discharges the chemical solution to the substrate W held by the spin chuck 62 at the processing position, the etching processing on the substrate W proceeds, for example. When the discharge nozzle 65 discharges pure water to the substrate W, pure water rinsing processing on the substrate W proceeds.

A maintenance worker performing a maintenance work on the plurality of substrate processing apparatuses 50 disposed in the clean room 40 wears the smart glass 10. The smart glass 10 is a type of a wearable terminal of a head mount display (HMD) system. The smart glass 10 is also a device for achieving augmented reality (AR) or mixed reality (MR). HoloLens (registered trademark) made by Microsoft Corporation, for example, can be used as the smart glass 10.

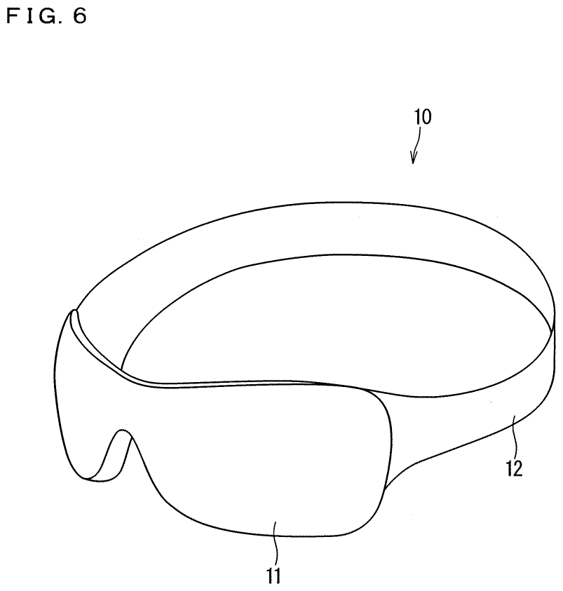

FIG. 6 is a perspective view illustrating an appearance of the smart glass 10. The smart glass 10 includes a visor 11 and a headband 12. The maintenance worker puts the headband 12 on a head to wear the smart glass 10. The maintenance worker can adjust a length of the headband 12 in accordance with a size of his/her head. A power source button, a light button, and a volume button, for example, are provided to the headband 12.

The visor 11 includes various sensors and a display. The display is a see-through holographic lens. That is to say, the display can display a three-dimensional vision on a visual space of the worker by a hologram, and light from an actual object passes through the display in the manner similar to a normal eyeglass lens. Accordingly, the maintenance worker wearing the smart glass 10 can also see a displayed three-dimensional vision while visually recognizing an actual object through the display.

Examples of the sensor of the visor 11 include a plurality of visible light cameras mainly taking an image in front of the visor 11, an infrared camera tracking a visual line of the maintenance worker, a depth sensor measuring a distance to a target object, and an inertial measurement sensor. The depth sensor measures a distance to a target object by a time of flight (ToF) system, for example. The inertial measurement sensor is made up of an accelerometer, a gyroscope, and a magnetometer, for example.

The smart glass 10 includes a built-in computer including a CPU, a memory, and a storage part, for example. A wireless communication mechanism is also provided to the smart glass 10, and the computer of the smart glass 10 is connected to the information communication network 5 using the wireless communication mechanism. Furthermore, a microphone, a speaker, and a battery, for example, are also provided to the smart glass 10.

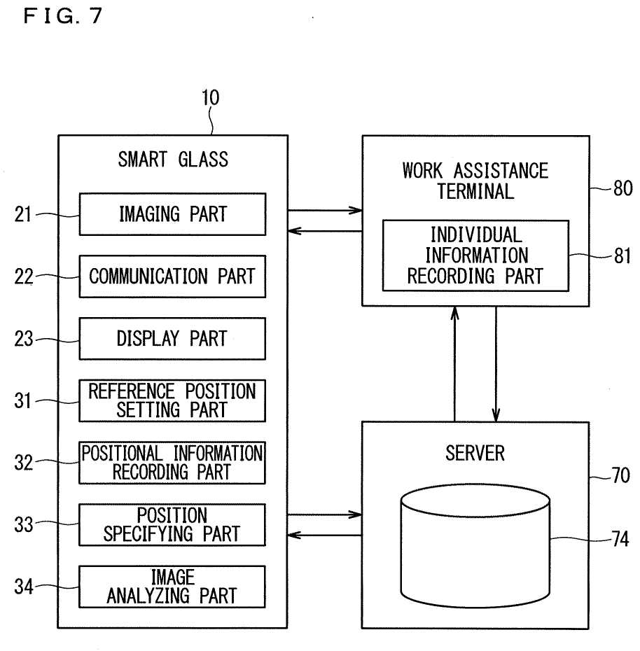

FIG. 7 is a block diagram illustrating a functional configuration of the smart glass 10, the server 70, and the work assistance terminal 80. The smart glass 10 includes an imaging part 21, a communication part 22, and a display part 23. The imaging part 21 includes a visible light camera provided to the visor 11 described above. The imaging part 21 includes four visible light cameras taking images of a front side and an obliquely front side, for example, and can take the image of a visual field range of the worker wearing the smart glass 10.

The communication part 22 includes the wireless communication mechanism of the smart glass 10 described above. The communication part 22 transmits and receives data to and from the work assistance terminal 80 and the server 70 via the information communication network 5. The communication part 22 can also transmit and receive the data to and from the controller 55 of the substrate processing apparatus 50.

The display part 23 includes a display of the visor 11 described above. The display part 23 includes a holographic processing device, and displays a three-dimensional vision in a predetermined spatial position by a hologram technique. The three-dimensional vision displayed by the display part 23 is not limited to video having a three-dimensional shape. A two-dimensional video such as a document is also applicable.

The smart glass 10 includes a reference position setting part 31, a positional information recording part 32, a position specifying part 33, and an image analyzing part 34. The reference position setting part 31, the positional information recording part 32, the position specifying part 33, and the image analyzing part 34 are function processing parts achieved by a CPU of the smart glass 10 executing a predetermined processing program. Processing contents of the reference position setting part 31, the positional information recording part 32, the position specifying part 33, and the image analyzing part 34 will be described in more detail hereinafter.

The work assistance terminal 80 and the server 70 are disposed in a plant of a vendor manufacturing the substrate processing apparatus 50 and undertaking a maintenance check, for example. The work assistance terminal 80 and the server 70 can have communication with the smart glass 10 via the information communication network 5. The work assistance terminal 80 and the server 70 can also have mutual communication with each other via the information communication network 5.

The work assistance terminal 80 and the server 70 are general computer systems. That is to say, the work assistance terminal 80 and the server 70 include a CPU that is a circuit for performing various types of computation processing, a ROM or read-only memory for storing a basic program therein, a RAM or readable/writable memory for storing various types of information therein, a storage part (for example, a magnetic disk or an SSD) for storing control software, data and the like therein, and a communication part having communication with the information communication network 5.

The work assistance terminal 80 is a computer for a work assistant on a vendor side to assist a work of a maintenance worker in the clean room 40. The work assistance terminal 80 includes an individual information recording part 81. The individual information recording part 81 is a function processing part achieved by a CPU in the work assistance terminal 80 executing a predetermined processing program.

The server 70 is a computer executing predetermined processing in accordance with request from the smart glass 10 and the work assistance terminal 80 in the work assistance system according to the present invention. Ther server 70 includes a storage part 74 having relatively large capacity. Large size data created by the smart glass 10 and the work assistance terminal 80 may be stored in the storage part 74. The server 70 is not a necessary element.

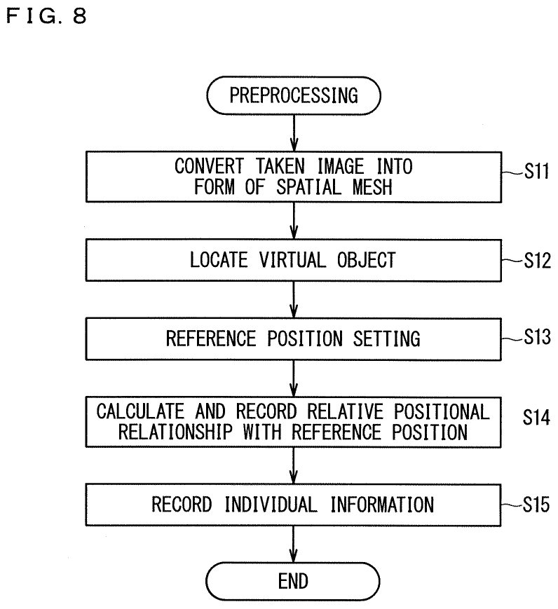

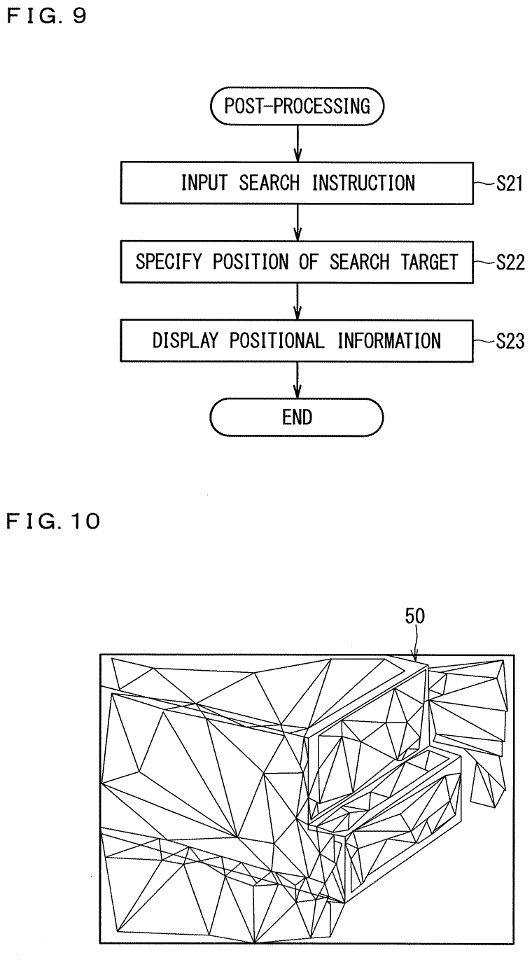

A work assistance method using the work assistance system having the above configuration is described next. FIG. 8 and FIG. 9 are flow charts each illustrating a procedure of the work assistance method according to the present invention. The work assistance method according to the present invention is divided into previous preparation processing and post-processing at a time of actually performing the work. FIG. 8 illustrates a procedure of the preprocessing, and FIG. 9 illustrates a procedure of the post-processing.

There is a description hereinafter that the maintenance worker performs an operation of selection or input, for example, using the three-dimensional vision displayed by the display part 23 of the smart glass 10 in some cases. This means that when the maintenance worker performs the operation of selection or input, for example, by a hand gesture on the three-dimensional vision displayed by the display part 23, the imaging part 21 takes an image of the hand gesture and detects the hand gesture, and the computer of the smart glass 10 recognizes that a predetermined operation is performed from a detection result thereof.

In the previous preparation process, an image of part of an inner side of the clean room 40 is taken by the smart glass 10, and the taken image is converted into a form of a spatial mesh (Step S11). This processing is performed by the maintenance worker wearing the smart glass 10 in the clean room 40 using the smart glass 10, for example.

The maintenance worker switches on a scan mode preset in the smart glass 10. The maintenance worker can select the scan mode from a menu screen displayed as a three-dimensional vision by the display part 23 by a hand gesture and switch on the scan mode, for example. The imaging part 21 takes the image of the hand gesture and detects the hand gesture, and the computer of the smart glass 10 recognizes that the scan mode is selected from a detection result thereof. Alternatively, the maintenance worker may press a predetermined button provided to the smart glass 10, thereby switching on the scan mode.

The maintenance worker takes an image of one or some of the plurality of substrate processing apparatuses 50 disposed in the clean room 40 by the imaging part 21 while the scan mode is in an on state. The image taken in the on state of the scan mode is scanned by the smart glass 10 and converted into the form of the spatial mesh, and the display part 23 displays the taken image overlapped with a mesh graphic.

FIG. 10 is a diagram illustrating an example of the taken image converted into the form of the spatial mesh. The imaging part 21 takes the image of the substrate processing apparatus 50, and the taken image is scanned and converted into the form of the spatial mesh. Thus, the mesh graphic expressed by a large number of triangle meshes is overlapped with the image of the substrate processing apparatus 50 and displayed. Even in a case where the same type and same form (that is to say, the same appearance) of plurality of substrate processing apparatuses 50 are disposed in the clean room 40, when the image of the plurality of substrate processing apparatuses 50 are taken and converted into the form of the spatial mesh, the mesh graphic is created in a different form because of a minute difference (for example, difference of a situation of a path) around each substrate processing apparatus 50. Accordingly, the taken image of the plurality of substrate processing apparatuses 50 in the clean room 40 can be identified by the difference of the mesh graphic.

After the taken image of the substrate processing apparatus 50 is converted into the form of the spatial mesh, the maintenance worker locates a virtual object on the spatial mesh in the image (Step S12). The virtual object is a virtual marker displayed by a three-dimensional vision by the display part 23. The maintenance worker locates the virtual object in an optional position around the substrate processing apparatus 50 by a hand gesture in the meshed image illustrated in FIG. 10, for example. Subsequently, the maintenance worker may fine-adjust the position of the virtual object using a remote controller screen displayed as a three-dimensional vision by the display part 23. The position where the virtual object is disposed may be overlapped with the substrate processing apparatus 50.

When the virtual object is disposed in the taken image of the substrate processing apparatus 50, the reference position setting part 31 of the smart glass 10 sets the position of the virtual object as a reference position with respect to the substrate processing apparatus 50 (Step S13). When the virtual object is disposed on the spatial mesh in the taken image, the reference position setting part 31 recognizes a position of the virtual object itself using a characteristic part of the spatial mesh. The characteristic part of the spatial mesh is a part having a characteristic mesh form such as a corner part of the substrate processing apparatus 50 in scanning, for example.

A relative positional relationship between the reference position which has been set and the substrate processing apparatus 50 is calculated and registered (Step S14). The maintenance worker overlaps a CAD diagram of the substrate processing apparatus 50 with a region of the substrate processing apparatus 50 in the taken image, for example. At this time, a 3D-CAD diagram is preferably overlapped with the substrate processing apparatus 50. The CAD diagram of the substrate processing apparatus 50 is previously created in designing the apparatus, and data thereof is stored in the storage part 74 of the server 70, for example. The smart glass 10 reads out the data of the CAD diagram of the substrate processing apparatus 50 from the server 70, and the display part 23 displays the CAD diagram in the taken image. The maintenance worker moves the displayed CAD diagram by a hand gesture to overlap the CAD diagram with the region of the substrate processing apparatus 50. Also at this time, the maintenance worker may fine-adjust the position of the CAD diagram using a remote controller screen displayed as a three-dimensional vision by the display part 23.

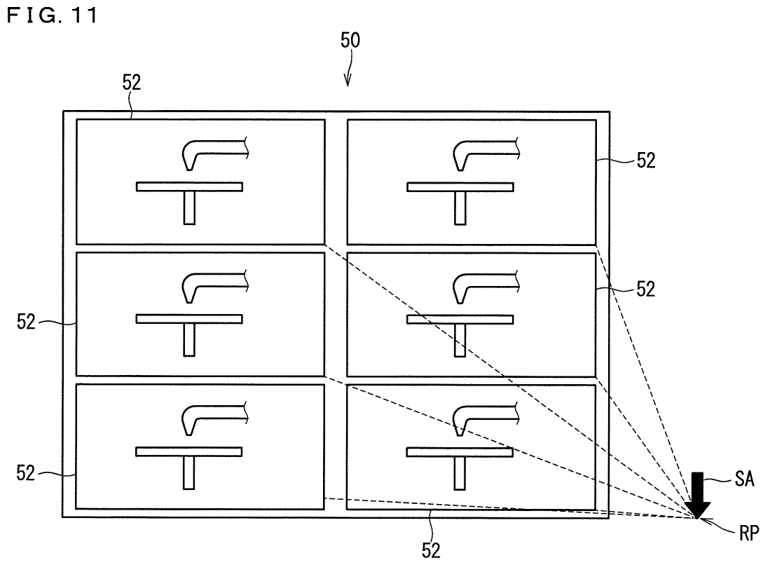

When the CAD diagram of the substrate processing apparatus 50 is accurately overlapped with the region of the substrate processing apparatus 50 in the taken image, the positional information recording part 32 of the smart glass 10 calculates a relative positional relationship between the reference position described above (the position of the virtual object) and each portion included in the substrate processing apparatus 50 and records the relative positional relationship. FIG. 11 is a diagram schematically illustrating the relative positional relationship between the reference position and each portion included in the substrate processing apparatus 50. When a virtual object SA is disposed, a position thereof is recorded as a reference position RP. A position of each portion included in the substrate processing apparatus 50 can be obtained by coordinate information included in the CAD data. The positional information recording part 32 calculates the relative positional relationship between the reference position RP and each portion included in the substrate processing apparatus 50 based on information of the reference position RP set in Step S13 and the coordinate information of the data of the CAD diagram overlapped with the substrate processing apparatus 50, and records the relative positional relationship.

The positional information recording part 32 calculates a relative positional relationship between a representative point (for example, a corner of the substrate processing apparatus 50) of the whole substrate processing apparatus 50 and the reference point RP and between each of the plurality of processing units 52 mounted to the substrate processing apparatus 50 and the reference position RP, and records the relative positional relationship. The positional information recording part 32 may further calculate a relative positional relationship between a portion provided to each processing unit 52 (for example, the spin chuck 62 and the discharge nozzle 65) and the reference position RP, and record the relative positional relationship. The data of the CAD diagram of the substrate processing apparatus 50 also includes coordinate information of each portion provided to such a processing unit 52. As for a driving portion such as the discharge nozzle 65, the coordinate information included in the data of the CAD diagram is based on a home position. Thus, calculated is the relative positional relationship between the driving portion located in the home position (a standby position described above in a case of the discharge nozzle 65) and the reference position RP.

The positional information recording part 32 needs not calculate the relative positional relationship for all of the portions included in the substrate processing apparatus 50. However, it is sufficient that the positional information recording part 32 calculates the relative positional relationship for a necessary portion. Examples of the portion included in the substrate processing apparatus 50 include the representative point of the whole substrate processing apparatus 50, the plurality of processing units 52 mounted to the substrate processing apparatus 50, and various portions provided to each processing unit 52. For example, the positional information recording part 32 may calculate a relative positional relationship between only the representative point of the whole substrate processing apparatus 50 and the reference position RP, and records the relative positional relationship. That is to say, the positional information recording part 32 calculates a relative positional relationship between at least one portion included in the substrate processing apparatus 50 and the reference position RP, and records the relative positional relationship.

It is sufficient that the positional information recording part 32 writes the calculated relative positional relationship between the reference position RP and each portion included in the substrate processing apparatus 50 in a database, for example, and records the relative positional relationship. Specifically, the positional information recording part 32 mutually associates an object name of a virtual object, a device number of the substrate processing apparatus 50 associated with the virtual object, and relative positional information of a portion included in the substrate processing apparatus 50, for example, with each other, and records data thereof in the database.

Next, necessary individual information is recorded for the portion included in the substrate processing apparatus 50 recorded in Step S14 (Step S15). The individual information is recorded by a work assistant using the work assistance terminal 80. Specifically, in response to an input operation on the work assistance terminal 80 by the work assistant, the individual information recording part 81 of the work assistance terminal 80 records the individual information in association with the portion of the substrate processing apparatus 50.

The individual information includes information such as alarm information, a work history, diagram information, a work procedure document, and a name label, for example. “The alarm information” is information regarding a past alarm history of a portion included in the substrate processing apparatus 50. “The work history” is information regarding a past maintenance history of a portion included in the substrate processing apparatus 50. “The diagram information” is a design diagram and a 3D-CAD diagram of a portion included in the substrate processing apparatus 50. “The work procedure document” is a manual of a procedure of a work on a portion included in the substrate processing apparatus 50 converted into a text form. The name label is a name of a portion included in the substrate processing apparatus 50 converted into a text form.

Data of these types of individual information is stored in the storage part 74 of the server 70, for example. The individual information recording part 81 associates the individual information of the portion included in the substrate processing apparatus 50 recorded in Step S14 with the portion and records the individual information. Specifically, it is sufficient that the individual information recording part 81 records a file name of data of the individual information in association with the portion included in the substrate processing apparatus 50 in the database described above.

The individual information recording part 81 records one, some, or all of the alarm information, the work history, the diagram information, the work procedure document, and the name label described above. That is to say, the individual information recording part 81 associates at least one piece of information selected from a group of the alarm information, the work history, the diagram information, the work procedure document, and the name label with the portion in the substrate processing apparatus 50 recorded in Step S14, and records at least one piece of information.

In the first embodiment, the processing of Step S11 to Step S15 is repetitively performed on all of the plurality of substrate processing apparatuses 50 disposed in the clean room 40 as the previous preparation processing. That is to say, the virtual object is disposed for all of the plurality of substrate processing apparatuses 50 disposed in the clean room 40, the relative positional relationship between the reference position and each portion included in the substrate processing apparatus 50 is calculated and recorded, and the individual information relating to the portion is recorded. The relative positional information and the individual information of each of the plurality of substrate processing apparatuses 50 are sequentially recorded in the database to constitute the database. It is sufficient that such previous preparation processing is performed when the plurality of substrate processing apparatuses 50 are disposed in the clean room 40, for example.

When the processing of conversion into the form of the spatial mesh in Step S11 is repetitively performed, conversion into the form of the spatial mesh is performed over a large range in the clean room 40. Accordingly, the smart glass 10 can recognize the position of the virtual object over a large range in the clean room 40. That is to say, the smart glass 10 can recognize in which position each of the plurality of disposed virtual objects is disposed in the clean room 40.

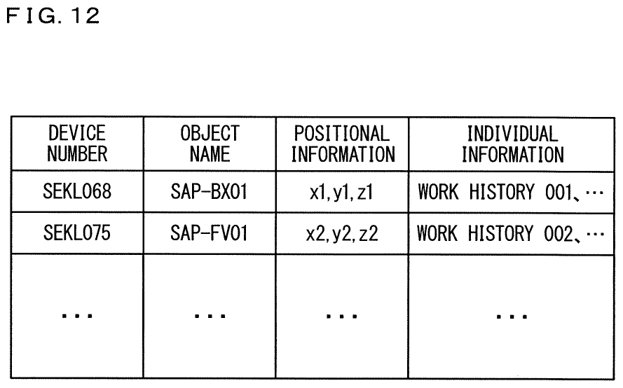

FIG. 12 is a diagram illustrating an example of a database in which positional information and individual information are recorded. As illustrated in FIG. 12, a device number for identifying the plurality of substrate processing apparatuses 50, an object name of the virtual object disposed with respect to the substrate processing apparatus 50, positional information (relative coordinate) indicating a relative positional relationship of the portion included in the substrate processing apparatus 50 with respect to the reference position RP, and individual information of the portion are mutually associated with each other and recorded in the database. Such a database is stored in the storage part 74 of the server 70, for example.

In FIG. 12, one piece of positional information is recorded for one substrate processing apparatus 50 for the sake of easier understanding. However, the positional information may be recorded for the plurality of portions (the processing unit 52 and the portions included in the processing unit 52) included in the substrate processing apparatus 50 as described above. The individual information may not necessarily be recorded.

Described next is post-processing in an actual work of the maintenance worker performed on the substrate processing apparatus 50 to be worked on with reference to FIG. 9. The first embodiment is based on a premise that the maintenance worker does not recognize the position of the substrate processing apparatus 50 in the clean room 40 to be worked on. Firstly, the maintenance worker inputs a search instruction of designating the substrate processing apparatus 50 to be worked on at an optional position in the clean room 40 (Step S21). Specifically, the maintenance worker wearing the smart glass 10 inputs the substrate processing apparatus 50 to be worked on from the smart glass 10 to execute the search instruction. The maintenance worker makes the display part 23 of the smart glass 10 display a virtual keyboard as a three-dimensional vision, and inputs a device number of the substrate processing apparatus 50 to be worked on from the keyboard, for example. It is also applicable that the maintenance worker makes the display part 23 of the smart glass 10 display device numbers of the plurality of substrate processing apparatuses 50 disposed in the clean room 40 in a list form to select a device number of the substrate processing apparatus 50 to be worked on from the list. A microphone is also provided to the smart glass 10, and the maintenance worker may designate the substrate processing apparatus 50 to be worked on by an audio input.

When the search input of designating the substrate processing apparatus 50 to be worked on is inputted from the smart glass 10, the position specifying part 33 of the smart glass 10 specifies the position of the substrate processing apparatus 50 in the clean room 40 (Step S22). The position specifying part 33 specifies the substrate processing apparatus 50 to be worked on from the database illustrated in FIG. 12 using the device number as a search key, and extracts the virtual object, the positional information, and the individual information, for example, associated with the substrate processing apparatus 50. The smart glass 10 recognizes where the virtual object is disposed in the clean room 40 using the spatial mesh. The positional information extracted from the database is a relative coordinate of the substrate processing apparatus 50 with respect to the reference position RP as the position where the virtual object is disposed. Accordingly, the position specifying part 33 of the smart glass 10 can specify the position of the substrate processing apparatus 50 to be worked on in the clean room 40 based on the reference position RP as the position where the virtual object is disposed associated with the substrate processing apparatus 50 to be worked on and the positional information as the relative coordinate with respect to the reference position RP.

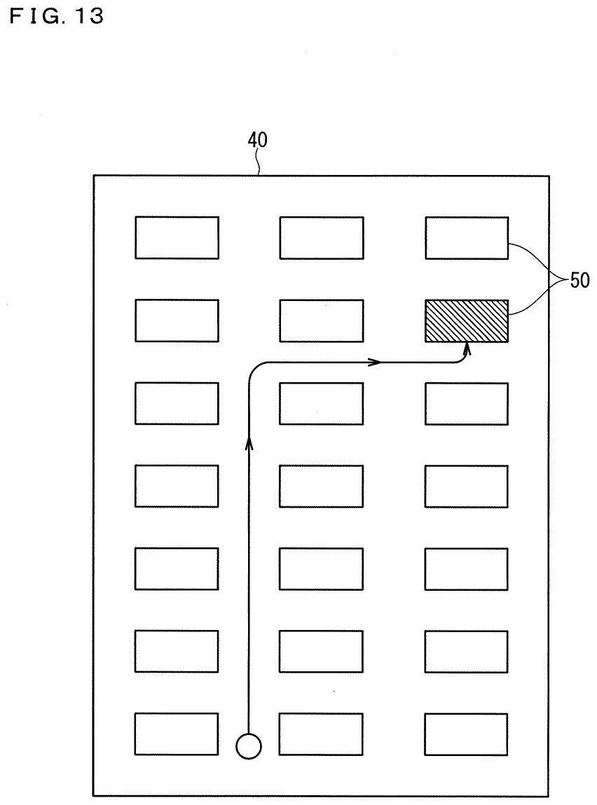

After the position of the substrate processing apparatus 50 to be worked on is specified, the position specifying part 33 makes the display part 23 display the positional information of the specified substrate processing apparatus 50 (Step S23). FIG. 13 is a diagram illustrating an example of the display of the positional information of the substrate processing apparatus 50. In the first embodiment, a guide route to the substrate processing apparatus 50 to be worked on in the clean room 40 is displayed as the positional information of the substrate processing apparatus 50. In order to display the guide route to any substrate processing apparatus 50, a position of the maintenance worker wearing the smart glass 10 also needs to be specified in addition to the position of the substrate processing apparatus 50 in the clean room 40. That is to say, a start point and an end point of the guide route needs to be specified.

The position of the substrate processing apparatus 50 to be worked on as the end point of the guide route is specified in Step S22 described above. In the meanwhile, the position of the maintenance worker wearing the smart glass 10 as the start point of the guide route can be specified when an image of a visual field which the maintenance worker sees through the smart glass 10 is converted into the form of spatial mesh. The maintenance worker switches on the scan mode while seeing an appropriate region in the clean room 40 through the smart glass 10. Accordingly, the image of the visual field which the maintenance worker sees through the smart glass 10 is scanned and converted into the form of the spatial mesh. The smart glass 10 performs pattern matching of the image converted into the form of the spatial mesh and the image converted into the form of the spatial mesh over the large range in the clean room 40 in the previous preparation processing, thereby specifying a current position of the maintenance worker in the clean room 40.

Subsequently, the position specifying part 33 of the smart glass 10 determines the guide route connecting the current position of the maintenance worker and the position of the substrate processing apparatus 50 to be worked on in the clean room 40. At this time, a shortest route is preferably determined as the guide route. After the guide route is determined, the display part 23 of the smart glass 10 displays the guide route from the current position of the worker to the substrate processing apparatus 50 to be worked on as illustrated in FIG. 13. Although displayed in FIG. 13 is the guide route in an image of seeing the inner side of the clean room 40 from an upper side in a plan view, the display is not limited thereto. For example, an arrow for guidance may be displayed on an actual path in the clean room 40 which the maintenance worker sees through the smart glass 10.

The maintenance worker proceeds along the guide route displayed by the smart glass 10, thereby being able to reliably reach the target substrate processing apparatus 50 to be worked. Then, the maintenance worker starts performing the necessary maintenance work on the target substrate processing apparatus 50.

In the first embodiment, the position where the virtual object is disposed is set as the reference position RP, and the relative positional relationship of the portion included in the substrate processing apparatus 50 with respect to the reference position RP is calculated and recorded to recognize the position of the substrate processing apparatus 50 in the clean room 40. When the search instruction of designating the substrate processing apparatus 50 to be worked on is inputted from the smart glass 10, the smart glass 10 specifies the position of the substrate processing apparatus 50 to be searched based on the relative positional relationship with respect to the reference position RP, and displays the positional information thereof. Specifically, the smart glass 10 displays the guide route to the substrate processing apparatus 50 to be searched. Accordingly, even when a large number of the substrate processing apparatuses 50 having the same appearance are disposed in the clean room 40, the maintenance worker can easily and reliably recognize the substrate processing apparatus 50 to be worked on, and can reach the target substrate processing apparatus 50 without mistake along the guide route.

### Second Embodiment

Next, a second embodiment according to the present invention will be described. A whole configuration of a work assistance system, locations of the plurality of substrate processing apparatuses 50 in the clean room 40, and a configuration of each substrate processing apparatus 50 in the second embodiment are the same as those in the first embodiment. In the second embodiment, the processing unit 52 provided in the substrate processing apparatus 50 is also to be searched.

Previous preparation processing in the second embodiment is basically the same as that in the first embodiment. As described above, the positional information recording part 32 of the smart glass 10 calculates the relative positional relationship between the representative point of the whole substrate processing apparatus 50 and the reference point RP and between each of the plurality of processing units 52 mounted to the substrate processing apparatus 50 and the reference position RP, and records the relative positional relationship. The positional information recording part 32 further calculates the relative positional relationship between the portion provided to each processing unit 52 (for example, the spin chuck 62 and the discharge nozzle 65) and the reference position RP, and records the relative positional relationship.

Accordingly, in the second embodiment, the positional information indicating the relative positional relationship between the plurality of processing units 52 and the portion provided to each processing unit 52, and the reference position RP is individually recorded in the database (refer to FIG. 12). The individual information thereof is also individually recorded.

The post-processing in the second embodiment is based on a premise that the maintenance worker is located near the substrate processing apparatus 50 to be worked on, but does not accurately recognize the processing unit 52 to be worked on. The maintenance worker inputs, to the smart glass 10, the search instruction of designating the processing unit 52 to be worked on in the plurality of processing units 52 mounted to the substrate processing apparatus 50.

When the search instruction of designating the processing unit 52 to be worked on is inputted from the smart glass 10, the position specifying part 33 of the smart glass 10 specifies the position of the processing unit 52 in the substrate processing apparatus 50. Specifically, the position specifying part 33 extracts the virtual object associated with the processing unit 52 to be searched, the positional information, and the individual information, for example, from the database. Then, the position specifying part 33 specifies the position of the processing unit 52 to be worked on based on the reference position RP as the position where the virtual object is disposed and the positional information as the relative coordinate with respect to the reference position RP.

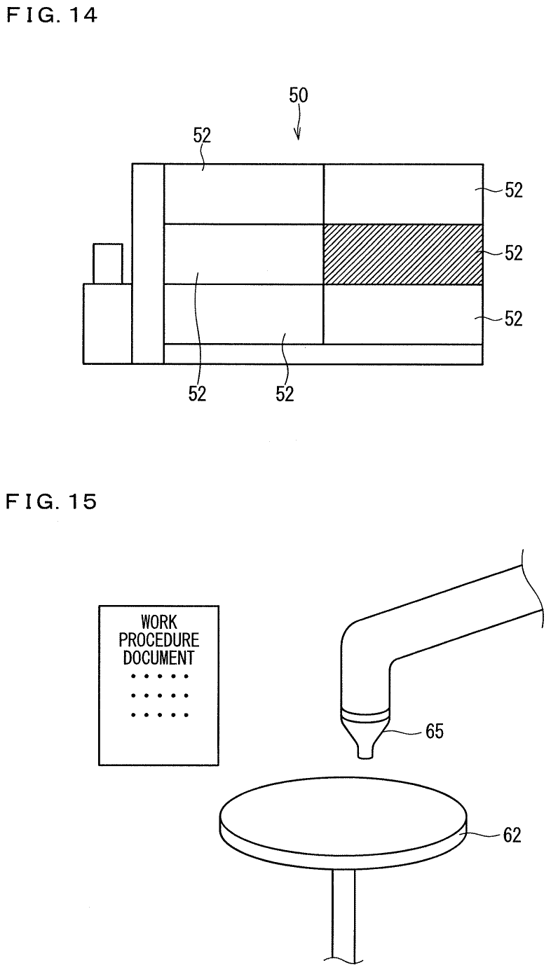

After the position of the processing unit 52 to be worked on is specified, the position specifying part 33 makes the display part 23 display the positional information of the specified processing unit 52. FIG. 14 is a diagram illustrating an example of the display of the positional information of the processing unit 52. In the second embodiment, in the image of the actual substrate processing apparatus 50 which the maintenance worker sees through the smart glass 10, the processing unit 52 to be worked on in the plurality of mounted plurality of processing units 52 is emphatically displayed. Specifically, the image of the actual substrate processing apparatus 50 which the maintenance worker sees through the smart glass 10 is scanned and converted into the form of the spatial mesh. Thus, the smart glass 10 can recognize that the substrate processing apparatus 50 is the apparatus including the processing unit 52 to be worked on. Then, the display part 23 of the smart glass 10 emphatically displays a region including the processing unit 52 to be worked on whose position is specified. Examples of the emphasized display include a method such as lightening, coloring, and displaying an arrow.

When the emphasized display is performed by the smart glass 10, the maintenance worker can reliably recognize the target processing unit 52 to be worked on. Then, the maintenance worker starts performing the necessary maintenance work on the target processing unit 52.

In the second embodiment, the position where the virtual object is disposed is set as the reference position RP, and the relative positional relationship of each processing unit 52 in the substrate processing apparatus 50 with respect to the reference position RP is calculated and recorded to recognize the position of each processing unit 52. When the search instruction of designating the processing unit 52 to be worked on is inputted from the smart glass 10, the smart glass 10 specifies the position of the processing unit 52 to be searched based on the relative positional relationship with respect to the reference position RP, and displays the positional information thereof. Specifically, the smart glass 10 emphatically displays the processing unit 52 to be searched in the substrate processing apparatus 50. Accordingly, even when the plurality of processing units 52 having similar shapes are provided in one substrate processing apparatus 50, the maintenance worker can easily and reliably recognize the processing unit 52 to be worked on, and erroneous recognition of the target can be prevented.

In the second embodiment, the relative positional relationship between a portion such as the spin chuck 62 or the discharge nozzle 65 provided to each processing unit 52 and the reference position RP is also recorded. Accordingly, the maintenance worker may input the search instruction of designating a portion in the processing unit 52 to the smart glass 10 in the post-processing. In this case, the position of the designated portion in the processing unit 52 is specified by the processing similar to the above processing, and positional information of the portion is displayed. In such a way, even when a large number of portions having similar shapes are provided in one substrate processing apparatus 50, the maintenance worker can easily and reliably recognize the portion in the processing unit 52 to be worked on, and erroneous recognition of the target can be prevented.

### Third Embodiment

Next, a third embodiment according to the present invention will be described. A whole configuration of a work assistance system, locations of the plurality of substrate processing apparatuses 50 in the clean room 40, and a configuration of each substrate processing apparatus 50 in the third embodiment are the same as those in the first embodiment. In the third embodiment, individual information associated with the portion included in the substrate processing apparatus 50 is displayed. Examples of the portion included in the substrate processing apparatus 50 include the representative point of the whole substrate processing apparatus 50, the plurality of processing units 52 mounted to the substrate processing apparatus 50, and various portions provided to each processing unit 52 as described above.

Previous preparation processing in the third embodiment is basically the same as that in the first embodiment. As described above, the positional information recording part 32 of the smart glass 10 calculates the relative positional relationship between the representative point of the whole substrate processing apparatus 50 and the reference point RP and between each of the plurality of processing units 52 mounted to the substrate processing apparatus 50 and the reference position RP, and records the relative positional relationship. The positional information recording part 32 further calculates the relative positional relationship between the portion provided to each processing unit 52 (for example, the spin chuck 62 and the discharge nozzle 65) and the reference position RP, and records the relative positional relationship.

The individual information recording part 81 of the work assistance terminal 80 records the individual information in association with the portion included in the substrate processing apparatus 50. The individual information includes at least one piece of information selected from a group of alarm information, a work history, diagram information, a work procedure document, and a name label.

In the post-processing in the third embodiment, the maintenance worker inputs a search instruction of designating any portion included in the substrate processing apparatus 50 to the smart glass 10. When the search instruction is inputted, a position of the portion to be searched is specified, and positional information for the portion is displayed in the manner similar to that in the first and second embodiments.

Furthermore, in the third embodiment, the smart glass 10 obtains the individual information for the portion to be searched, and displays the individual information. Specifically, the smart glass 10 extracts the individual information associated with the portion to be searched from the database. Then, the display part 23 of the smart glass 10 displays the extracted individual information. FIG. 15 is a diagram illustrating an example of display of the individual information. In the example in FIG. 15, the maintenance worker inputs, from the smart glass 10, the search instruction of designating the discharge nozzle 65 on which the maintenance work is to be performed. Then, a region of the discharge nozzle 65 to be worked on is emphatically displayed in the image inside the processing unit 52 which the maintenance worker sees through the smart glass 10. The individual information associated with the discharge nozzle 65 (“work procedure document” in the example in FIG. 15) is also displayed together with the emphasized region.

Accordingly, the maintenance worker can confirm the work procedure document for the discharge nozzle 65 to be worked on without spreading a paper work procedure document by a hand. Accordingly, the maintenance worker can perform a necessary work while sequentially confirming the work procedure document even when the hand is filled with a tool, example.

In the third embodiment, when the maintenance worker inputs the search instruction of designating any portion included in the substrate processing apparatus 50 from the smart glass 10, the individual information is also displayed in addition to the positional information of the portion. Since the hand of the maintenance worker is filled in performing the maintenance work in many cases, it is a cumbersome work to spread a paper document. According to the third embodiment, the individual information relating to the portion included in the substrate processing apparatus 50 is displayed as the three-dimensional vision by the smart glass 10. Thus, the maintenance worker can confirm the individual information even while working with both hands.

### Fourth Embodiment

Next, a fourth embodiment according to the present invention will be described. A whole configuration of a work assistance system, locations of the plurality of substrate processing apparatuses 50 in the clean room 40, and a configuration of each substrate processing apparatus 50 in the fourth embodiment are the same as those in the first embodiment. In the fourth embodiment, the positional information of the accessory unit 48 of the substrate processing apparatus 50 is also displayed.

As illustrated in FIG. 3, the accessory unit 48 is provided to each of the plurality of substrate processing apparatuses 50 separately from a body. The substrate processing apparatus 50 is disposed on the floor 45 of the clean room 40, and the accessory unit 48 is provided below the floor 45. The plurality of substrate processing apparatuses 50 and the plurality of accessory units 48 are provided to correspond to each other on a one-to-one basis. Since the accessory unit 48 is provided to the floor different from the substrate processing apparatus 50 as the main part, when the maintenance worker performs the maintenance work on the accessory unit 48 of the substrate processing apparatus 50, it is difficult to recognize which is a unit corresponding to the substrate processing apparatus 50 in the plurality of accessory units 48 disposed in the different floor.

Thus, in the fourth embodiment, the maintenance worker wearing the smart glass 10 also locates the virtual object around the accessory unit 48 in addition to locating the virtual object around the substrate processing apparatus 50. In the manner similar to the first embodiment, the maintenance worker converts a taken image including the accessory unit 48 taken by the smart glass 10 into a form of a spatial mesh. Then, the maintenance worker locates the virtual object on the spatial mesh. The virtual object may be disposed in an optional position around the accessory unit 48.

Since the virtual object is disposed in the taken image of the accessory unit 48, the reference position setting part 31 of the smart glass 10 sets the position of the virtual object as an accessory reference position with respect to the accessory unit 48. Then, the positional information recording part 32 of the smart glass 10 calculates the relative positional relationship between the accessory reference position and the portion included in the accessory unit 48, and records the relative positional relationship. The portion included in the accessory unit 48 is any position (representative point) in the accessory unit 48. It is sufficient that the relative positional relationship is calculated by overlapping a 3D-CAD diagram of the accessory unit 48 with the accessory unit 48, for example, in the manner similar to the first embodiment. The calculated relative positional relationship between the accessory reference position and the portion included in the accessory unit 48 is recorded in the database as the positional information.

The reference position RP of the substrate processing apparatus 50 and the accessory reference position of the accessory unit 48 of the substrate processing apparatus 50 are associated with each other in recording the database. Specifically, an object name of the virtual object disposed with respect to the substrate processing apparatus 50 and an object name of the virtual object disposed with respect to the accessory unit 48 of the substrate processing apparatus 50 have a common part, for example. Accordingly, both virtual objects are linked to each other, and the reference position RP of the substrate processing apparatus 50 and the accessory reference position of the accessory unit 48 of the substrate processing apparatus 50 are associated with each other.

In the post-processing in the fourth embodiment, the maintenance worker inputs the search instruction of designating the accessory unit 48 of the substrate processing apparatus 50 to be worked on from the smart glass 10. When the search instruction is inputted from the smart glass 10, the position specifying part 33 of the smart glass 10 specifies the position of the designated accessory unit 48 of the substrate processing apparatus 50. Specifically, the position specifying part 33 specifies the accessory unit 48 corresponding to the object name linked to the object name corresponding to the substrate processing apparatus 50 to be searched from the database. Then, the position specifying part 33 extracts the positional information associated with the specified accessory unit 48, and specifies the position of the accessory unit 48 to be worked on based on the accessory reference position and the positional information as the relative coordinate with respect to the accessory reference position.

After the position of the accessory unit 48 to be worked on is specified, the position specifying part 33 makes the display part 23 display the positional information of the specified accessory unit 48. As the display of the positional information, it is sufficient to display the guide route to the accessory unit 48 to be worked on in the manner similar to the first embodiment, for example.

The maintenance worker proceeds along the guide route displayed by the smart glass 10, thereby being able to reliably reach the accessory unit 48 of the target substrate processing apparatus 50 to be worked even when the accessory unit 48 is located in the floor different from the clean room 40 where the substrate processing apparatus 50 is disposed. Then, the maintenance worker starts performing the necessary maintenance work on the target accessory unit 48.

In the fourth embodiment, the virtual object linked to the virtual object disposed in the substrate processing apparatus 50 is disposed to the accessory unit 48 of the substrate processing apparatus 50, and the reference position RP of the substrate processing apparatus 50 and the accessory reference position of the accessory unit 48 are associated with each other. Then, the relative positional relationship of the accessory unit 48 with respect to the accessory reference position is calculated and recorded to recognize the position of the accessory unit 48 while being linked to the substrate processing apparatus 50. When the search instruction of designating the accessory unit 48 of the substrate processing apparatus 50 to be worked on is inputted from the smart glass 10, the smart glass 10 specifies the accessory unit 48 corresponding to the substrate processing apparatus 50 to be searched, specifies the position of the target accessory unit 48 based on the relative positional relationship with respect to the accessory reference position, and displays the positional information thereof. Accordingly, even when the accessory unit 48 is provided to the floor different from the clean room 40 in which the substrate processing apparatus 50 is disposed, the accessory unit 48 to be worked on can be easily and reliably recognized, and erroneous recognition of the target can be prevented.

### Fifth Embodiment

Next, a fifth embodiment according to the present invention will be described. A whole configuration of a work assistance system, locations of the plurality of substrate processing apparatuses 50 in the clean room 40, and a configuration of each substrate processing apparatus 50 in the fifth embodiment are the same as those in the first embodiment. In the fifth embodiment, a portion included in the substrate processing apparatus 50 is recognized based on an image taken by the smart glass 10 in the post-processing.

Previous preparation processing in the fifth embodiment is basically the same as that in the first embodiment. The maintenance worker takes images of the plurality of substrate processing apparatuses 50 in the clean room 40 while the scan mode is in the on state. The taken images are scanned by the smart glass 10 and converted into the form of the spatial mesh. The maintenance worker locates the virtual object on the spatial mesh in the taken images. The position of the virtual object is set as the reference position RP, and the relative positional relationship between the portion included in the substrate processing apparatus 50 and the reference position RP is calculated and recorded.

In the post-processing in the fifth embodiment, the maintenance worker operates a detection button of the smart glass 10 while keeping any substrate processing apparatus 50 or processing unit 52 within a visual field in the clean room 40. The maintenance worker may operate the detection button displayed as the three-dimensional vision by the display part 23 or press the detection button provided to the smart glass 10. The smart glass 10 takes an image of the visual field of the maintenance worker in response to the operation on the detection button, and scans and converts the taken image into the form of the spatial mesh.

The image analyzing part 34 (refer to FIG. 7) of the smart glass 10 analyzes the taken image converted into the meshed pattern and identifies an element included in the substrate processing apparatus 50 or the processing unit 52 in the image. For example, the image analyzing part 34 identifies the element of the spin chuck 62 and the discharge nozzle 65, for example, included in the processing unit 52 from the taken image.

At this time, it is sufficient that the image analyzing part 34 identifies the element by a pattern matching of the image taken in the previous preparation processing and the image taken in the post-processing. It is also applicable that a learned model is constituted by machine learning such as deep learning from a large number of images which have been previously taken and the element is identified from the taken images using the leaned model.

When the element included in the substrate processing apparatus 50 or the processing unit 52 is identified from the taken image, the display part 23 of the smart glass 10 displays the identified element in a list form, for example. Accordingly, the maintenance worker can recognize the element provided to the substrate processing apparatus 50 or the processing unit 52 whose image is taken. It is also applicable that when the maintenance worker selects a necessary element from a list, positional information of the element is displayed.

In the fifth embodiment, when the maintenance worker takes the image of the substrate processing apparatus 50 or the processing unit 52 and inputs the detection instruction from the smart glass 10, the image analyzing part 34 performs predetermined image processing on the taken image and identify the element included in the substrate processing apparatus 50 or the processing unit 52 to display the positional information. In this manner, the maintenance worker can easily and reliably recognize the element included in the substrate processing apparatus 50 or the processing unit 52, and erroneous recognition of the target can be prevented.

### Modification Example

While the embodiments according to the present invention have been described hereinabove, various modifications of the present invention are possible in addition to those described above without departing from the scope and spirit of the present invention. For example, in the first embodiment, the image is taken by the smart glass 10 over the large range in the clean room 40 and is converted into the form of the spatial mesh. However, huge amounts of data are necessary for the conversion into the form of the spatial mesh. Thus, an image of a part of an area in the clean room 40 may be taken to be converted into the form of the spatial mesh. When only a part of the clean room 40 is converted into the form of the spatial mesh, it is difficult to recognize the position of the virtual object in the whole clean room 40. Thus, such a configuration is based on a premise that the maintenance worker roughly recognizes the position of the substrate processing apparatus 50 to be worked on in the clean room 40 and can reach near the position thereof. Such a configuration is based on a premise that an image of at least an area near the substrate processing apparatus 50 to be worked on is taken and converted into the form of the spatial mesh.

When the maintenance worker inputs the search instruction of designating the substrate processing apparatus 50 to be worked on at a position near the substrate processing apparatus 50, the area near the substrate processing apparatus 50 is converted into the form of the spatial mesh. When the virtual object is disposed with respect to the substrate processing apparatus 50, the position of the substrate processing apparatus 50 in the spatial mesh is specified. Then, the specified substate processing apparatus 50 which the maintenance worker sees through the smart glass 10 is emphatically displayed, for example. Also in this manner, the maintenance worker can easily and reliably recognize the substrate processing apparatus 50 to be worked on, and erroneous recognition of the target can be prevented.

In the first embodiment, the operation assistant records the individual information using the operation assistance terminal 80. However, the configuration is not limited thereto. When computing power and storage capacity of the smart glass 10 are sufficiently high, the maintenance worker may record the individual information using the smart glass 10. Alternatively, the server 70 may record the individual information.

In the first embodiment, the relative positional relationship between each portion included in the substrate processing apparatus 50 and the reference position RP is individually calculated. However, instead of this configuration, only the relative positional relationship between the representative point of the whole substrate processing apparatus 50 and the reference position RP may be calculated and recorded to collectively record the relative positional relationship of each portion included in the substrate processing apparatus 50, for example. In this case, the positional relationship between the representative point of the whole substrate processing apparatus 50 and the other portion is obtained from coordinate information included in data of a CAD diagram, for example. That is to say, the coordinate information included in the data of the CAD diagram is used to indirectly record the relative positional relationship of each portion included in the substrate processing apparatus 50.

It is also applicable that in the first embodiment, one point of a surface (for example a front surface or a back surface) appropriate to work on the substrate processing apparatus 50 is a representative point of the whole substrate processing apparatus 50, and calculate and record a relative positional relationship between the surface appropriate to work on the substrate processing apparatus 50 and the reference position RP. According to such a configuration, a guide route to the surface appropriate to work on the substrate processing apparatus 50 is displayed, and the maintenance worker can efficiently start performing the maintenance work.

In each embodiment described above, the virtual object is disposed on the spatial mesh to position a virtual space and an actual space based on the taken image and the scanned spatial information. Although this method is one of visual positioning service/system (VPS) techniques of positioning the virtual space and the actual space, a method of positioning the virtual space and the actual space is not limited thereto described above.

In each embodiment described above, the maintenance worker uses the smart glass 10. However, the configuration is not limited thereto, but the maintenance worker may use a tablet terminal or a mobile terminal such as a smartphone in place of the smart glass 10. That is to say, it is sufficient to use a mobile terminal including an imaging part and a communication part. When a tablet terminal, for example, is used, the hand of the maintenance worker is filled with the tablet terminal; thus, it is preferable to use a wearable terminal such as the smart glass 10.

The substrate processing apparatus 50 is not limited to a substrate cleaning apparatus. Any semiconductor manufacturing apparatus is applicable as long as it performs predetermined processing on a substrate such as a heat treatment apparatus, an exposure apparatus, a coating-developing apparatus, a measuring apparatus, or an inspection apparatus. When the substrate processing apparatus 50 is the substrate cleaning apparatus, a single wafer type cleaning apparatus cleaning a substrate one by one or a batch-type cleaning apparatus collectively cleaning a plurality of substrates is applicable.

### EXPLANATION OF REFERENCE SIGNS

5 information communication network
10 smart glass
21 imaging part
22 communication part
23 display part
31 reference position setting part
32 positional information recording part
33 position specifying part
34 image analyzing part
40 clean room
48 accessory unit
50 substrate processing apparatus
52 accessory unit
70 server
80 work assistance terminal
81 individual information recording part
60 processing chamber
61 rotation holding part
62 spin chuck
65 discharge nozzle
RP reference position
SA virtual object
W substrate

1. A work assistance method on a substrate processing apparatus performing predetermined processing on a substrate, comprising:
(a) setting a reference position with respect to the substrate processing apparatus in a taken image obtained by taking an image of a substrate processing apparatus by a mobile terminal including an imaging part and a communication part;
(b) calculating and recording a relative positional relationship between at least one portion included in the substrate processing apparatus and the reference position; and
(c) specifying a position of a portion included in a substrate processing apparatus to be searched from recorded contents in the (b) when a search instruction of designating a portion included in a substrate processing apparatus to be worked on is inputted from the mobile terminal and displaying positional information of the position.

2. The work assistance method according to claim 1, wherein
in the (c), a search instruction of designating the substrate processing apparatus to be worked on is inputted, a position of the substrate processing apparatus to be searched is specified, and a guide route to the substrate processing apparatus is displayed.

3. The work assistance method according to claim 1, further comprising
(d) associating individual information of a portion recorded in the with the portion and recording the individual information, wherein
the mobile terminal further displays the individual information associated with a portion included in the substrate processing apparatus to be searched.

4. The work assistance method according to claim 3, wherein
the individual information includes at least one piece of information selected from a group of alarm information, a work history, diagram information, a work procedure document, and a name label.

5. The work assistance method according to claim 1, wherein
in the (a), a virtual object is disposed on a spatial mesh obtained by scanning the taken image to set the reference position.

6. The work assistance method according to claim 1, wherein
the substrate processing apparatus includes a plurality of processing units,
in the (b), a relative positional relationship between a portion included in each of the plurality of processing units and the reference position is individually calculated and recorded, and
in the (c), positional information of a portion included in each of the processing units is displayed when search instruction of designating any portion included in the plurality of processing units is inputted from the mobile terminal.

7. The work assistance method according to claim 6, wherein
in the (b), a CAD diagram of the substrate processing apparatus is overlapped with the substrate processing apparatus in the taken image, and a relative positional relationship between a portion included in each of the plurality of processing units and the reference position is individually calculated.

8. The work assistance method according to claim 6, wherein
an accessory unit as an accessory of the substrate processing apparatus is provided separately from the substrate processing apparatus,
in the (a), an accessory reference position associated with the reference position is further set for the accessory unit,
in the (b), a relative positional relationship between a portion included in the accessory unit and the accessory reference position is further recorded, and
in the (c), positional information of the accessory unit is displayed when a search instruction of designating the accessory unit is inputted from the mobile terminal.

9. The work assistance method according to claim 6, wherein
in the (c), predetermined image processing is performed on a taken image to identify an element included in each of the processing units and display the positional information when an image of any of the plurality of processing units is taken and a detection instruction is inputted in the mobile terminal.

10. The work assistance method according to claim 1, wherein
the mobile terminal is a smart glass.

11. A work assistance system on a substrate processing apparatus performing predetermined processing on a substrate, comprising:
a plurality of substrate processing apparatuses;
a mobile terminal including a imaging part and a communication part;
a reference position setting part setting a reference position with respect to at least one of the plurality of substrate processing apparatuses in a taken image obtained by taking an image of the at least one of the plurality of substrate processing apparatuses by the mobile terminal;
a positional information recording part calculating and recording a relative positional relationship between at least one portion included in the substrate processing apparatuses and the reference position; and
a position specifying part specifying a position of a portion included in a substrate processing apparatus to be searched from recorded contents by the positional information recording part when a search instruction of designating a portion included in the substrate processing apparatus to be worked on is inputted from the mobile terminal and displaying positional information of the position by the mobile terminal.

12. The work assistance system according to claim 11, further comprising
an individual information recording part associating individual information of a portion recorded by the positional information recording part with the portion and recording the individual information, and
the position specifying part further displays the individual information associated with the substrate processing apparatus to be searched.

13. The work assistance system according to claim 12, wherein
the individual information includes at least one piece of information selected from a group of alarm information, a work history, diagram information, a work procedure document, and a name label.

14. The work assistance system according to claim 11, wherein the mobile terminal is a smart glass.
